(19) United States
(12) Patent Application Publication
(10) Pub. No.: US 2024/0414966 A1
(43) Pub. Date: Dec. 12, 2024

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Changchang LIU, Beijing (CN); Fei FANG, Beijing (CN); Hongting LU, Beijing (CN); Ling SHI, Beijing (CN)

(21) Appl. No.: 18/697,009

(22) PCT Filed: Aug. 9, 2023
(86) PCT No.: PCT/CN2023/111943

§ 371 Date: Mar. 29, 2024

(30) Foreign Application Priority Data
Aug. 30, 2022 (CN) 202211050964.8

(51) Int. Cl. H10K 59/131; G09G 3/3233; H10K 59/121; H10K 59/65

(52) U.S. Cl. CPC H10K 59/131; G09G 3/3233; H10K 59/1213; H10K 59/1216; H10K 59/65; G09G 2300/0426; G09G 2310/08

(57) ABSTRACT

A display substrate, comprising: a substrate, at least one pixel circuit group, multiple data lines, and a first power line. The pixel circuit group comprises two first pixel circuits adjacent to each other in a first direction. The pixel circuit group is electrically connected to the first power line. One of the first pixel circuits in the pixel circuit group is electrically connected to a first data line, and the other one is electrically connected to a second data line. The first data line, the second data line, and the first power line all extend in a second direction. The first and second data lines are respectively on two opposite sides of the first power line in the first direction and are both adjacent to the first power line. The two first pixel circuits in the pixel circuit group are respectively on the two sides of the first power line.

### CROSS-REFERENCE TO RELATED APPLICATIONS

The present application is a U.S. National Phase Entry of International Application PCT/CN2023/111943 having an international filing date of Aug. 9, 2023, which claims priority to Chinese Patent Application No. 202211050964.8, filed to the CNIPA on Aug. 30, 2022 and entitled “Display Substrate and Display Apparatus”, the contents of which should be construed as being incorporated herein by reference in their entireties.

### TECHNICAL FIELD

The present disclosure relates to, but is not limited to, the field of display technologies, in particular to a display substrate and a display apparatus.

### BACKGROUND

An Organic Light Emitting Diode (OLED) and a Quantum dot Light Emitting Diode (QLED) are active light emitting display devices and have advantages of self-luminescence, a wide viewing angle, a high contrast ratio, low power consumption, a very high response speed, lightness and thinness, bendability, and a low cost, etc.

### SUMMARY

The following is a summary of subject matter described herein in detail. The summary is not intended to limit the scope of protection of the claims.

At least one embodiment of the present disclosure provides a display substrate and a display apparatus.

In one aspect, at least one embodiment of the present disclosure provides a display substrate including a base substrate, a plurality of data lines, a first power supply line, and at least one pixel circuit group. The base substrate at least includes a first display region. At least one pixel circuit group is located in the first display region. The pixel circuit group includes two first pixel circuits adjacent in a first direction. A plurality of data lines are electrically connected to the at least one pixel circuit group and are configured to provide a data signal to the at least one pixel circuit group, and the plurality of data lines include a first data line and a second data line. The first power supply line is electrically connected to the at least one pixel circuit group and is configured to provide a power supply signal to the at least one pixel circuit group. One first pixel circuit in the pixel circuit group is electrically connected to the first data line, and another first pixel circuit in the pixel circuit group is electrically connected to the second data line. The first data line, the second data line, and the first power supply line all extend along a second direction, and the first direction intersects with the second direction. The first data line and the second data line are respectively located on opposite sides of the first power supply line along the first direction, and both the first data line and the second data line are adjacent to the first power supply line. Two first pixel circuits in the pixel circuit group are respectively located on two sides of the first power supply line.

In some exemplary implementations, the two first pixel circuits in the pixel circuit group are substantially symmetrical with respect to the first power supply line.

In some exemplary implementations, the display substrate further includes a first initial signal line and a first reset control line. Each first pixel circuit at least includes a drive transistor and a first transistor, wherein a first electrode of the first transistor is electrically connected with the first initial signal line, a second electrode of the first transistor is electrically connected with a second electrode of the drive transistor, and a gate of the first transistor is electrically connected with the first reset control line. An active layer of the first transistor of the first pixel circuit extends along the first direction, and the gate of the first transistor extends along the second direction.

In some exemplary implementations, the first reset control line extends along the first direction and is integrally formed with gates of first transistors of the two first pixel circuits of the pixel circuit group; and the first reset control line is located on a side of active layers of the first transistors of the two first pixel circuits away from the drive transistor in the second direction.

In some exemplary implementations, the first initial signal line extends along the first direction, and an orthographic projection of the first initial signal line on the base substrate is overlapped with an orthographic projection of the first reset control line on the base substrate.

In some exemplary implementations, the first initial signal line is located on a side of the first reset control line away from the base substrate.

In some exemplary implementations, active layers of the first transistors of the two first pixel circuits in the pixel circuit group are of an integral structure.

In some exemplary implementations, the display substrate further includes a first connection electrode. The active layers of the first transistors of the two first pixel circuits in the pixel circuit group are electrically connected with the first connection electrode through a same first via hole, and the first connection electrode is electrically connected with the first initial signal line.

In some exemplary implementations, the display substrate further includes a plurality of second initial signal lines extending along the second direction and the first pixel circuit is electrically connected to the second initial signal lines. A second initial signal line electrically connected to one of the first pixel circuits in the pixel circuit group is located on a side of the first data line away from the first power supply line, and a second initial signal line electrically connected to the other first pixel circuit is located on a side of the second data line away from the first power supply line.

In some exemplary implementations, the display substrate further includes an initial connection line extending along the first direction, which is electrically connected to the plurality of second initial signal lines, and an orthographic projection of the initial connection line on the base substrate is overlapped with an orthographic projection of the first initial signal line electrically connected to the first pixel circuits on the base substrate.

In some exemplary implementations, the initial connection line and the plurality of second initial signal lines are of an integral structure, and the initial connection line is located on a side of the first initial signal line away from the base substrate.

In some exemplary implementations, the first power supply line, the first data line, and the second data line are disposed in a same layer, and the first power supply line is located on a side of the plurality of second initial signal lines away from the base substrate.

In some exemplary implementations, the display substrate further includes a third initial signal line and a first signal line. The first pixel circuit is also electrically connected to the third initial signal line and the first signal line, both of which extend along the first direction. An orthographic projection of the third initial signal line on the base substrate is overlapped with an orthographic projection of the first signal line on the base substrate, and the third initial signal line is located on a side of the first signal line away from the base substrate.

In some exemplary implementations, the display substrate further includes a second reset control line. The first pixel circuit further includes an eighth transistor, wherein a first electrode of the eighth transistor is electrically connected to the third initial signal line, a second electrode of the eighth transistor is electrically connected to a first electrode of the drive transistor, and a gate of the eighth transistor is electrically connected to the second reset control line. A connection position between the eighth transistor and the third initial signal line is located on a side of the second reset control line close to the drive transistor.

In some exemplary implementations, the first pixel circuit further includes a fifth transistor and a storage capacitor; a first electrode of the fifth transistor is electrically connected to the first power supply line, a second electrode of the fifth transistor is electrically connected to a first electrode of the drive transistor, and a gate of the fifth transistor is electrically connected to a light emitting control line; a first electrode of the storage capacitor is electrically connected with the gate of the drive transistor, and a second electrode of the storage capacitor is electrically connected with the first power supply line; and active layers of the fifth transistors of the two first pixel circuits in the pixel circuit group are of an integral structure, and the second electrodes of the storage capacitors of the two first pixel circuits are of an integral structure.

In some exemplary implementations, the display substrate further includes a second connection electrode. Active layers of fifth transistors of the two first pixel circuits in the pixel circuit group and second electrodes of storage capacitors of the two first pixel circuits are all electrically connected with the second connection electrode; and the second connection electrode is electrically connected with the first power supply line.

In some exemplary implementations, the first display region includes a plurality of display island regions spaced apart from each other, and light transmission regions located between adjacent display island regions; at least one display island region of the plurality of display island regions includes: the at least one pixel circuit group and at least one first light emitting element; the first pixel circuits in the pixel circuit group are electrically connected with the at least one first light emitting element, and the first pixel circuits are configured to drive the at least one first light emitting element to emit light; and the first pixel circuits in adjacent display island regions are electrically connected to each other through a transparent connection line.

In some exemplary implementations, the display substrate further includes a second display region located on at least one side of the first display region, and the second display region includes a plurality of second pixel circuits arranged on the base substrate and a plurality of second light emitting elements, wherein at least one second pixel circuit of the plurality of second pixel circuits is electrically connected to at least one second light emitting element of the plurality of second light emitting elements, and the at least one second pixel circuit is configured to drive the at least one second light emitting element to emit light. A light transmittance of the first display region is greater than that of the second display region.

In another aspect, an embodiment of the present disclosure provides a display apparatus, which includes the aforementioned display substrate and a sensor located on a non-display side of the display substrate, and an orthographic projection of the sensor on the display substrate is overlapped with the first display region of the display substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a display substrate according to at least one embodiment of the present disclosure.

FIG. 2 is an equivalent circuit diagram of a pixel circuit according to at least one embodiment of the present disclosure.

FIG. 3 is a working timing diagram of the pixel circuit provided in FIG. 2.

FIG. 4 is a schematic partial view of a first display region according to at least one embodiment of the present disclosure.

FIG. 5 is partial top view of a first display region according to at least one embodiment of the present disclosure.

FIG. 6A is a partial cross-sectional view taken along Q-Q′ direction in FIG. 5.

FIG. 6B is a cross-sectional view of a part taken along R-R′ direction in FIG. 5.

FIG. 7 is a schematic partial view of a first display region after a first semiconductor layer is formed in FIG. 5.

FIG. 8 is a schematic partial view of a first display region after a first conductive layer is formed in FIG. 5.

FIG. 9 is a schematic diagram of the first conductive layer in FIG. 8.

FIG. 10 is a schematic partial view of a first display region after a second conductive layer is formed in FIG. 5.

FIG. 11 is a schematic partial view of a first display region after a second semiconductor layer is formed in FIG. 5.

FIG. 12 is a schematic partial view of a first display region after a third conductive layer is formed in FIG. 5.

FIG. 13 is a schematic diagram of the third conductive layer in FIG. 12.

FIG. 14 is a schematic partial view of a first display region after a fifth insulation layer is formed in FIG. 5.

FIG. 15 is a schematic partial view of a first display region after a fourth conductive layer is formed in FIG. 5.

FIG. 16 is a schematic diagram of a fourth conductive layer in FIG. 15.

FIG. 17 is a schematic partial view of a first display region after a seventh insulation layer is formed in FIG. 5.

FIG. 18 is a schematic diagram of the fifth conductive layer in FIG. 5.

FIG. 19 is another schematic partial view of a first display region according to at least one embodiment of the present disclosure.

FIG. 20 is a schematic partial view of a first display region after a fourth conductive layer is formed in FIG. 19.

FIG. 21 is a schematic diagram of a fourth conductive layer in FIG. 20.

FIG. 22 is a schematic diagram of a display apparatus according to at least one embodiment of the present disclosure.

### DETAILED DESCRIPTION

The embodiments of the present disclosure will be described below with reference to the drawings in detail. Implementations may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be a fixed connection, a detachable connection, or an integral connection; it may be a mechanical connection or a connection; it may be a direct connection, an indirect connection through a middleware, or internal communication inside two elements. Those of ordinary skills in the art may understand meanings of the aforementioned terms in the present disclosure according to situations.

In the specification, a transistor refers to an element which at least includes three terminals, i.e., a gate (gate electrode), a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, a first electrode may be a drain and a second electrode may be a source, or, a first electrode may be a source and a second electrode may be a drain. In addition, the gate may also be referred to as a control electrode. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification.

In the specification, “electrical connection” includes connection of composition elements through an element with a certain electrical action. The “element with the certain electrical action” is not particularly limited as long as electrical signals between the connected constituent elements may be transmitted. Examples of the “element with the certain electrical action” not only include an electrode and a wiring, but also include a switching element such as a transistor, a resistor, an inductor, a capacitor, another element with a plurality of functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In this specification, a circle, oval, triangle, rectangle, trapezoid, pentagon or hexagon, etc. is not strictly speaking, but may be an approximate circle, oval, triangle, rectangle, trapezoid, pentagon or hexagon, etc. Some small deformations due to tolerances may exist, for example, guide angles, curved edges and deformations thereof may exist.

A “light transmittance” in the present specification refers to an ability of light to pass through a medium, and is a percentage of luminous flux passing through a transparent or translucent body to its incident luminous flux.

In the specification, “about” and “substantially” refer to that a boundary is not defined strictly and a case within a process and measurement error range is allowed. In the present disclosure, “substantially the same” refers to a case where numerical values differ by less than 10%.

In the present specification, “A extends along a B direction” means that A may include a main portion and a secondary portion connected to the main portion, the main portion is a line, a line segment, or a strip-shaped body, the main portion extends along the B direction, and a length of the main portion extending along the B direction is greater than a length of the secondary portion extending along another direction. “A extends in a B direction” in the present specification always means “a main portion of A extends in a B direction”.

In the present specification, the adjacency of traces A and B means that there are no other traces between traces A and B.

At least one embodiment of the present disclosure provides a display substrate, including a base substrate, at least one pixel circuit group, a plurality of data lines, and a first power supply line. The base substrate at least includes a first display region. At least one pixel circuit group is located in the first display region. The pixel circuit group includes two first pixel circuits adjacent in a first direction. A plurality of data lines are electrically connected to the at least one pixel circuit group and are configured to provide data signals to the at least one pixel circuit group, and the plurality of data lines include a first data line and a second data line. The first power supply line is electrically connected to the at least one pixel circuit group and is configured to provide power supply signals to the at least one pixel circuit group. One first pixel circuit in the pixel circuit group is electrically connected to the first data line, and another first pixel circuit in the pixel circuit group is electrically connected to the second data line. The first data line, the second data line and the first power supply line all extend along the second direction. The first data line and the second data line are respectively located on opposite sides of the first power supply line along the first direction, and both the first data line and the second data line are adjacent to the first power supply line. Two first pixel circuits in the pixel circuit group are respectively located on two sides of the first power supply line. Herein, the first direction may intersect with the second direction, for example, the first direction may be perpendicular to the second direction.

In this embodiment, the two first pixel circuits in the pixel circuit group are respectively located on both sides of the first power supply line, which may mean that at least portions of the two first pixel circuits are arranged on opposite sides of the first power supply line, and the two first pixel circuits may be partially overlapped with the first power supply line.

The display substrate according to this embodiment may meet requirement of higher light transmittance, for example, the display substrate of this example may be a Full Display With Camera (FDC) display substrate. However, this embodiment is not limited thereto.

In the display substrate according to this embodiment, the two first pixel circuits in the pixel circuit group may be respectively located on two sides of the first power supply line, and the two first pixel circuits share one first power supply line, which may save space occupied by the pixel circuits and improve light transmittance of the first display region. Moreover, the first data line and the second data line are respectively located on opposite sides of the first power supply line, and mutual interference between the first data line and the second data line may be shielded by using the first power supply line.

In some exemplary implementations, two first pixel circuits in the pixel circuit group may be substantially symmetrical with respect to the first power supply line. In this embodiment, the two first pixel circuits in the pixel circuit group are substantially symmetrical with respect to the first power supply line, which may mean that all transistors in the two first pixel circuits are symmetrical with respect to the first power supply line, or most of the transistors have a symmetrical relationship with respect to the first power supply line, and several (e.g. one or two) transistors are not fully symmetrical with respect to the first power supply line. Herein, a quantity of transistors having a symmetrical relationship in each first pixel circuit may be greater than a quantity of transistors having no symmetrical relationship. In this example, two first pixel circuits in the pixel circuit group may have a mirror image design with respect to the first power supply line, and the two first pixel circuits may share one first power supply line, which thus may save the space occupied by the pixel circuits and improve the light transmittance of the first display region.

In some exemplary implementations, the display substrate may further include a first initial signal line and a first reset control line. The first pixel circuit may at least include a drive transistor and a first transistor. A first electrode of the first transistor is electrically connected to the first initial signal line, a second electrode of the first transistor is electrically connected to a second electrode of the drive transistor, and a gate of the first transistor is electrically connected to the first reset control line. An active layer of the first transistor of the first pixel circuit may extend along the first direction, and a gate of the first transistor may extend along the second direction. Arrangement mode of the first transistor of this example may be beneficial to compressing a size of the first pixel circuit along the second direction.

In some exemplary implementations, the first reset control line may extend along the first direction and be integrally formed with the gates of the first transistors of the two first pixel circuits of the pixel circuit group. The first reset control line may be located on a side of the active layers of the first transistors of the two first pixel circuits away from the drive transistor in the second direction. For example, the first initial signal line may extend along the first direction, and an orthographic projection of the first initial signal line on the base substrate may be overlapped with an orthographic projection of the first reset control line on the base substrate. In this example, the first initial signal line is overlapped with the first reset control line, which may save space occupied by traces and is beneficial to increasing the light transmittance of the first display region.

In some exemplary implementations, the display substrate may further include a plurality of second initial signal lines extending along the second direction. The first pixel circuit is electrically connected to the second initial signal line. For example, the second initial signal line electrically connected to one of the first pixel circuits in the pixel circuit group may be located on a side of the first data line away from the first power supply line, and the second initial signal line electrically connected to another first pixel circuit may be located on a side of the second data line away from the first power supply line. In this example, the second initial signal line is configured to extend along the second direction, which may avoid excessive traces extending along the first direction and is beneficial to increasing the light transmittance of the first display region.

In some exemplary implementations, the display substrate may further include a third initial signal line and a first signal line. The first pixel circuit may also be electrically connected to the third initial signal line and the first signal line. The third initial signal line and the first signal line may both extend along the first direction. An orthographic projection of the third initial signal line on the base substrate may be overlapped with an orthographic projection of the first signal line on the base substrate, and the third initial signal line may be located on a side of the first signal line away from the base substrate. In some examples, the first signal line may include a light emitting control line. In this example, the first signal line is overlapped with the third initial signal line, which may save space occupied by traces and is beneficial to increasing the light transmittance of the first display region.

In some exemplary implementations, the first display region may include a plurality of display island regions spaced apart from each other and light transmission regions located between adjacent display island regions. At least one of the plurality of display island regions may include at least one pixel circuit group and at least one first light emitting element. The first pixel circuit in the pixel circuit group is electrically connected to the at least one first light emitting element, and the first pixel circuit is configured to drive the at least one first light emitting element to emit light. The first pixel circuits in adjacent display island regions are electrically connected through a transparent connection line.

Solutions of the embodiments will be described below through some examples.

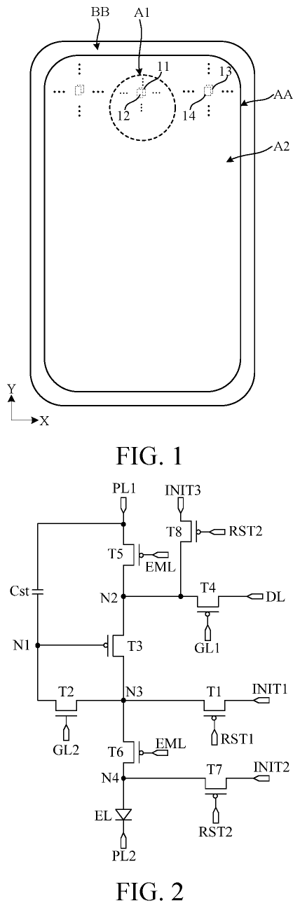

FIG. 1 is a schematic diagram of a display substrate according to at least one embodiment of the present disclosure. In some examples, as shown in FIG. 1, the display substrate may include a display region AA and a peripheral region BB surrounding a periphery of the display region AA. The display region AA of the display substrate may include a first display region A1 and a second display region A2 located on at least one side of the first display region A1. For Example, the second display region A2 may surround the first display region A1. The first display region A1 may be located at a top middle position in the display region AA. However, this embodiment is not limited thereto. For example, the first display region A1 may be located at another position such as an upper left corner or an upper right corner of the display region AA.

In some examples, as shown in FIG. 1, the display region AA may be in a shape of a rectangle, e.g., a rounded rectangle. The first display region A1 may be circular or elliptical. However, this embodiment is not limited thereto. For example, the first display region may be rectangular, pentagonal, hexagonal or in another shape.

In some examples, as shown in FIG. 1, the first display region A1 may be a light transmitting display region and may also be referred to as a Full Display with Camera (FDC) region. The second display region A2 may be a non-light transmitting display region, and may also be referred to as a normal display region. A light transmittance of the first display region A1 is greater than a light transmittance of the second display region A2. For example, an orthographic projection of hardware such as a photosensitive sensor (such as a camera and, an infrared sensor) on the display substrate may be located within the first display region A1 of the display substrate. In some examples, the first display region A1 may be circular and a size of the orthographic projection of the photosensitive sensor on the display substrate may be less than or equal to a size of the first display region A1. However, this embodiment is not limited thereto. In some other examples, the first display region may be rectangular, and the size of the orthographic projection of the photosensitive sensor on the display substrate may be less than or equal to a size of an inscribed circle of the first display region.

In some examples, the display region AA may at least include a plurality of regularly arranged pixel units, a plurality of gate lines (for example, including a scan line, a reset control line, and a light emitting control line) extending along a first direction X, a plurality of data lines extending along a second direction Y, and a power supply line. The first direction X and the second direction Y may be located in a same plane, and the first direction X intersects with the second direction Y, for example, the first direction X may be perpendicular to the second direction Y.

In some examples, one pixel unit of the display region AA may include three sub-pixels, and the three sub-pixels may be a red sub-pixel, a green sub-pixel, and a blue sub-pixel, respectively. However, this embodiment is not limited thereto. In some examples, one pixel unit may include four sub-pixels, wherein the four sub-pixels may be a red sub-pixel, a green sub-pixel, a blue sub-pixel, and a white sub-pixel respectively.

In some examples, at least one sub-pixel may include a pixel circuit and a light emitting element. The pixel circuit may be configured to drive a light emitting element connected thereto. For example, the pixel circuit may be configured to provide a driving current for driving the light emitting element to emit light. The pixel circuit may include a plurality of transistors and at least one capacitor. For example, the pixel circuit may be of a 3T1C structure, an 8T1C structure, a 7T1C structure, or a 5T1C structure. Herein, in the above circuit structure, T refers to a thin film transistor, C refers to a capacitor, a number before T represents a quantity of thin film transistors in the circuit, and a number before C represents a quantity of capacitors in the circuit.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under drive of a pixel circuit corresponding to the light emitting element. A color of light emitted from the light emitting element may be determined as required. In some examples, the light emitting element may include an anode, a cathode, and an organic emitting layer located between the anode and the cathode. The anode of the light emitting element may be electrically connected with a corresponding pixel circuit. However, this embodiment is not limited thereto.

In some examples, a shape of the light emitting element may be a rectangle, a rhombus, a pentagon, or a hexagon. When one pixel unit includes three sub-pixels, light-emitting elements of the three sub-pixels may be arranged side by side horizontally, side by side vertically, or in a delta arrangement. When one pixel unit includes four sub-pixels, light-emitting elements of the four sub-pixels may be arranged side by side horizontally, side by side vertically, or in a manner to form a square. However, this embodiment is not limited thereto.

FIG. 2 is an equivalent circuit diagram of a pixel circuit according to at least one embodiment of the present disclosure. The pixel circuit of an exemplary embodiment is described by taking a 8T1C structure as an example.

In some examples as, shown in FIG. 2, the pixel circuit of this example may include eight transistors (i.e., a first transistor T1 to an eighth transistor T8) and one storage capacitor Cst. The first transistor T1 is also referred to as a first reset transistor, the second transistor T2 is also referred to as a threshold compensation transistor, the third transistor T3 is also referred to as a drive transistor, the fourth transistor T4 is also referred to as a data writing transistor, the fifth transistor T5 is also referred to as a first light emitting control transistor, the sixth transistor T6 is also referred to as a second light emitting control transistor, the seventh transistor T7 is also referred to as a second reset transistor, and the eighth transistor T8 is also referred to as a third reset transistor. The light emitting element EL may include an anode, a cathode and an organic emitting layer arranged between the anode and the cathode.

In some examples, the first transistor T1, the third transistor T3 to the eighth transistor T8 may be first type transistors, which may be, for example, P-type transistors, and the second transistor T2 may be a second type transistor, which may be, for example, an N-type transistor. However, this embodiment is not limited thereto. For example, the plurality of transistors of the first pixel circuit may be all P-type transistors or may be all N-type transistors.

In some examples, the first type transistors (e.g., the first transistor T1, the third transistor T3 to the eighth transistor T8) of the pixel circuit may be low temperature poly-crystalline silicon thin film transistors, and the second type transistors (e.g., the second transistor T2) of the pixel circuit may be oxide thin film transistors. Low Temperature Poly Silicon (LTPS) is used for an active layer of a low temperature poly silicon thin film transistor and an oxide semiconductor (Oxide) is used for an active layer of an oxide thin film transistor. A low temperature poly-crystalline silicon thin film transistor has advantages, such as a high mobility, and fast charging, etc., while an oxide thin film transistor has advantages, such as a low leakage current, etc. The low temperature poly-silicon thin film transistor and the oxide thin film transistor are integrated on one display substrate to form a low temperature poly-crystalline oxide (LTPS+ Oxide) display substrate, and advantages of both the low temperature poly-crystalline silicon thin film transistor and the oxide thin film transistor can be utilized, which can achieve low frequency drive, reduce power consumption, and improve display quality.

In some examples, as shown in FIG. 2, the pixel circuit may be electrically connected with a first scan line GL1, a second scan line GL2, a data line DL, a first power supply line PL1, a second power supply line PL2, a light emitting control line EML, a first initial signal line INIT1, a second initial signal line INIT2, a third initial signal line INIT3, a first reset control line RST1, and a second reset control line RST2. The first power supply line PL1 is configured to provide a constant first voltage signal VDD to the pixel circuit, the second power supply line PL2 is configured to provide a constant second voltage signal VSS to the pixel circuit, and the first voltage signal VDD is greater than the second voltage signal VSS. The first scan line GL1 is configured to provide a first scan signal SCAN1 to the pixel circuit. The second scan line GL2 is configured to provide a second scan signal SCAN2 to the pixel circuit. The data line DL is configured to provide a data signal DATA to the pixel circuit. The light emitting control line EML is configured to provide a light emitting control signal EM to the pixel circuit. The first reset control line RST1 is configured to provide a first reset control signal RESET1 to the pixel circuit. The second reset control line is configured to provide a second reset control signal RESET2 to the pixel circuit.

In some examples, as shown in FIG. 2, a gate of the third transistor T3 is electrically connected with a first node N1, a first electrode of the third transistor T3 is electrically connected with a second node N2, and a second electrode of the third transistor T3 is electrically connected with a third node N3. A gate of the fourth transistor T4 is electrically connected with the first scan line GL1, a first electrode of the fourth transistor T4 is electrically connected with the data line DL, and a second electrode of the fourth transistor T4 is electrically connected with the second node N2. A gate of the second transistor T2 is connected to the second scan signal line GL2, a first electrode of the second transistor T2 is electrically connected with the first node N1, and a second electrode of the second transistor T2 is electrically connected with the third node N3. A gate of the fifth transistor T5 is electrically connected with the light emitting control line EML, a first electrode of the fifth transistor T5 is electrically connected with the first power supply line PL1, and a second electrode of the fifth transistor T5 is electrically connected with the second node N2. A gate of the sixth transistor T6 is electrically connected with the light emitting control line EML, a first electrode of the sixth transistor T6 is electrically connected with the third node N3, and a second electrode of the sixth transistor T6 is electrically connected with a fourth node N4. A gate of the first transistor T1 is electrically connected with the first reset control line RST1, a first electrode of the first transistor T1 is electrically connected with the first initial signal line INIT1, and a second electrode of the first transistor T1 is electrically connected with the third node N3. A gate of the seventh transistor T7 is electrically connected with the second reset control line RST2, a first electrode of the seventh transistor T7 is electrically connected with the second initial signal line INIT2, and a second electrode of the seventh transistor T7 is electrically connected with the fourth node N4. A gate of the eighth transistor T8 is electrically connected with the second reset control line RST2, a first electrode of the eighth transistor T8 is electrically connected with the third initial signal line INIT3, and a second electrode of the eighth transistor T8 is electrically connected with the second node N2. A first electrode of the storage capacitor Cst is electrically connected with the first node N1, and a second electrode of the storage capacitor Cst is electrically connected with the first power supply line PL1.

In this example, the first node N1 is a connection point for the storage capacitor Cst, the second transistor T2, and the third transistor T3. The second node N2 is a connection point for the fifth transistor T5, the fourth transistor T4, the eighth transistor T8, and the third transistor T3. The third node N3 is a connection point for the first transistor T1, the third transistor T3, the second transistor T2, and the sixth transistor T6. The fourth node N4 is a connection point for the sixth transistor T6, the seventh transistor T7, and the light emitting element EL.

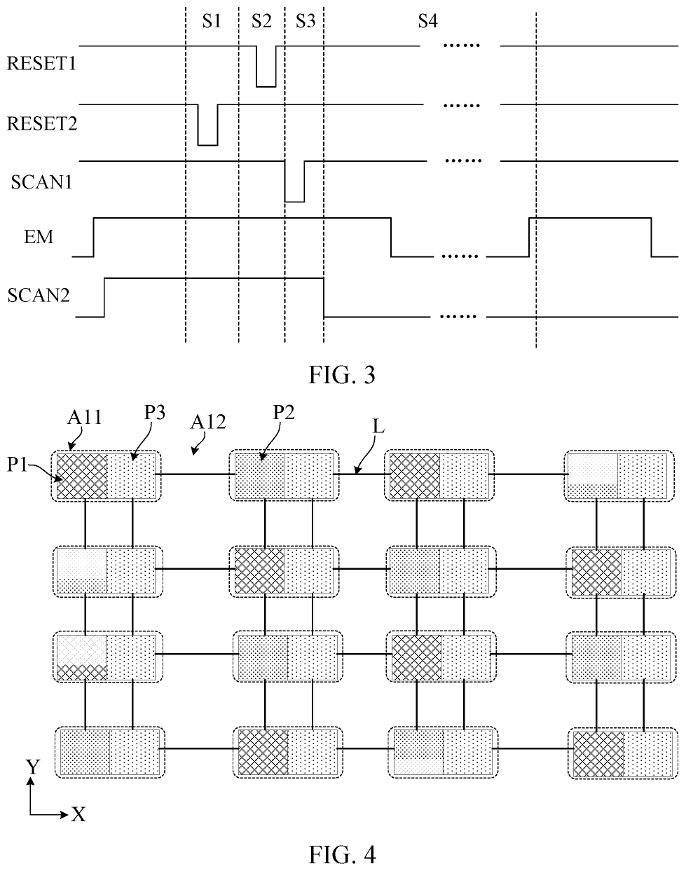

FIG. 3 is a working timing diagram of the pixel circuit provided in FIG. 2. A working process of the pixel circuit shown in FIG. 2 will be described below with reference to FIG. 3. Herein, the first transistor T1, the third transistor T3 to the eighth transistor T8 of the pixel circuit are P-type transistors, and the second transistor T2 is an N-type transistor.

In some examples, as shown in FIG. 2 and FIG. 3, during one frame of display period, the working process of the pixel circuit may at least include a first stage S1, a second stage S2, a third stage S3, and a fourth stage S4.

The first stage S1 is referred to as a first reset stage. In the first stage S1, the second reset control signal RESET2 provided by the second reset control line RST2 is a low level signal to turn on the seventh transistor T7 and the eighth transistor T8, and the second scan signal SCAN2 provided by the second scan line GL2 is a high level signal to turn on the second transistor T2. The eighth transistor T8 is turned on so that the third initial signal provided by the third initial signal line INIT3 is provided to the second node N2. The seventh transistor T7 is turned on so that the second initial signal provided by the second initial signal line INIT2 is provided to the fourth node N4 to initialize the fourth node N4. The first scan signal SCAN1 provided by the first scan line GL1 is a high level signal, the first reset control signal RESET1 provided by the first reset control line RST1 is a high level signal, and the light emitting control signal EM provided by the light emitting control line EML is a high level signal, so that the fourth transistor T4, the first transistor T1, the fifth transistor T5 and the sixth transistor T6 are turned off. In this stage, the light emitting element EL does not emit light.

The second stage S2 is referred to as a second reset stage. In the second stage S2, the first reset control signal RESET1 provided by the first reset control line RST1 is a low level signal, and the first transistor T1 is turned on. The second scan signal SCAN2 provided by the second scan line GL2 is a high level signal, and the second transistor T2 is turned on. The first transistor T1 and the second transistor T2 are turned on such that a first initial signal provided by the first initial signal line INIT1 is provided to the first node N1 to initialize the first node N1. The second reset control signal RESET2 provided by the second reset control line RST2 is a high level signal, the first scan signal SCAN1 provided by the first scan line GL1 is a high level signal, and the light emitting control signal EM provided by the light emitting control line EML is a high level signal, so that the seventh transistor T7, the eighth transistor T8, the fourth transistor T4, the fifth transistor T5 and the sixth transistor T6 are turned off. In this stage, the light emitting element EL does not emit light.

The third stage S3 is referred to as a data writing stage or a threshold compensation stage. In the third stage S3, the first scan signal SCAN1 provided by the first scan line GL1 is a low level signal, and the fourth transistor T4 is turned on. The second scan signal SCAN2 provided by the second scan line GL2 is a high level signal, and the second transistor T2 is turned on. At this stage, the first electrode of the storage capacitor Cst is at a low level and the third transistor T3 is turned on. The second transistor T2, the fourth transistor T4 and the fourth transistor T3 are turned on, so that a data voltage Vdata output by the data line DL is provided to the first node N1 through the second node N2, the turned-on third transistor T3, the third node N3, and the turned-on second transistor T2, and the storage capacitor Cst is charged with a difference between the data voltage Vdata output by the data line DL and a threshold voltage of the third transistor T3. A voltage of the first electrode (i.e., the first node N1) of the storage capacitor Cst is Vdata−|Vth|, wherein Vdata is the data voltage output by the data line DL, and Vth is the threshold voltage of the third transistor T3. The first reset control signal RESET1 provided by the first reset control line RST1 is a high level signal, the second reset control signal RESET2 provided by the second reset control line RST2 is a high level signal, and the light emitting control signal EM provided by the light emitting control line EML is a high level signal, so that the first transistor T1, the seventh transistor T7, the eighth transistor T8, the fifth transistor T5 and the sixth transistor T6 are turned off.

In the fourth stage S4, the light emitting control signal EM provided by the light emitting control line EML can be switched from the high level signal to a low level signal, so that the fifth transistor T5 and the sixth transistor T6 are turned on. The second scan signal SCAN2 provided by the second scan line GL2 is a low level signal, so that the second transistor T2 is turned off. The first scan signal SCAN1 provided by the first scan line GL1, the first reset control signal RESET1 provided by the first reset control line RST1, and the second reset control signal RESET2 provided by the second reset control line RST2 are high level signals, so that the fourth transistor T4, the first transistor T1, the seventh transistor T7, and the eighth transistor T8 are turned off. The first voltage signal VDD outputted by the first power supply line PL1 may provide a drive voltage to the anode of the light emitting element EL through the turned-on fifth transistor T5, the third transistor T3, and the sixth transistor T6, driving the light emitting element EL to emit light.

In a drive process of the pixel circuit, a drive current flowing through the third transistor T3 is determined by a voltage difference between the gate and the first electrode of the third transistor T3. Since the voltage of the first node N1 is Vdata-|Vth|, the drive current of the third transistor T3 is as follows.

I=K×(Vgs−Vth)²−K×[(VDD−Vdata+|Vth|)−Vth]²=K×[VDD−Vdata]²

Herein, I is the drive current flowing through the third transistor T3, that is, a drive current for driving the light emitting element, K is a constant, Vgs is the voltage difference between the gate and the first electrode of the third transistor T3, Vth is the threshold voltage of the third transistor T3, Vdata is the data voltage outputted by the data line DL, and VDD is the first voltage signal outputted by the first power supply line PL1.

It may be seen from the above formula that a current flowing through the light emitting element is independent of the threshold voltage of the third transistor T3. Therefore, the pixel circuit according to this embodiment may better compensate the threshold voltage of the third transistor T3. Moreover, the pixel circuit provided in this embodiment can improve poor display caused by low frequency and improve a display effect of the light emitting element.

In some examples, as shown in FIG. 1, the first display region A1 of the display substrate may be provided with a plurality of first light emitting elements 12 and a plurality of first pixel circuits 11. At least one first pixel circuit 11 is electrically connected with at least one first light emitting element 12, and is configured to drive the at least one first light emitting element 12 to emit light. The second display region A2 may be provided with a plurality of second light emitting elements 14 and a plurality of second pixel circuits 13. At least one second pixel circuit 13 is electrically connected with at least one second light emitting element 14, and is configured to drive the at least one second light emitting element 14 to emit light. For example, a plurality of first pixel circuits 11 are electrically connected with a plurality of first light emitting elements 12 in one to one correspondence, and a plurality of second pixel circuits 13 are electrically connected with a plurality of second light emitting elements 14 in one to one correspondence.

FIG. 4 is a schematic partial view of a first display region according to at least one embodiment of the present disclosure. In some examples, as shown in FIG. 4, in a plane parallel to the display substrate, the first display region may include a plurality of display island regions A11 spaced apart from each other, and light transmission regions A12 between adjacent display island regions A11. Each display island region A11 may be configured to display an image, and each light transmission region A12 may be configured to provide a light transmission space. Shapes of the plurality of display island regions A11 may be substantially the same, and each display island region A11 may have a smooth edge, thereby reducing a light diffraction effect and being beneficial to improvement of a shooting effect. The display island regions A11 in the first display region may be independent of each other, and the light transmission regions A12 in the first display region may be communicated with each other, and the light transmission regions A12 may surround the display island regions A11.

In some examples, as shown in FIG. 4, in a plane parallel to the display substrate, a plurality of display island regions A11 may be arranged in a plurality of rows and columns. The plurality of display island regions A11 arranged along the first direction X may be referred to as a row of display island regions, and the plurality of display island regions A11 arranged along the second direction Y may be referred to as a column of display island regions. Display island regions of adjacent row may not be misaligned in the second direction Y, and display island regions of adjacent column may not be misaligned in the first direction X. However, this embodiment is not limited thereto. For example, the display island regions of adjacent rows may be misaligned in the second direction Y, and the display island regions of adjacent columns may be misaligned in the first direction X.

In some examples, as shown in FIG. 4, the plurality of sub-pixels of the first display region may include a first sub-pixel P1 emitting a first color light, a second sub-pixel P2 emitting a second color light, and a third sub-pixel P3 emitting a third color light. For example, the first pixel circuit of the plurality of sub-pixels of the first display region may be arranged in an array, and the first light emitting element of a plurality of sub-pixels may be arranged according to a Pentile structure. For example, the first light emitting element emitting the first color light and the first light emitting element emitting the second color light may be alternately arranged in the first direction X and the second direction Y, and the first light emitting elements emitting the third color light may be located between adjacent first light emitting elements emitting the first color light and the first light emitting elements emitting the second color light in the first direction X. For example, the light of the first color may be red light, the light of the second color may be blue light, and the light of the third color light may be green light. That is, the first light emitting element emitting the first color light may be a red light emitting element, the first light emitting element emitting the second color light may be a blue light emitting element, and the first light emitting element emitting the third color light may be a green light emitting element.

In some examples, as shown in FIG. 4, a single display island region A11 of the first display region may include two sub-pixels. For example, two first pixel circuits of two sub-pixels are one pixel circuit group. One first pixel circuit may be configured to drive one first light emitting element electrically connected to emit light. In this example, the single display island region A11 may include one pixel circuit group. The first pixel circuits in the adjacent display island region A11 may be electrically connected through a transparent connection line L. The transparent connection line L may be made of a transparent conductive material, for example, indium tin oxide (ITO). The number and arrangement mode of the transparent connection lines are not limited in this embodiment, as long as the signal transmission between the first pixel circuits in the adjacent display island region may be achieved. In some other examples, the single display island region may include a plurality of pixel circuit groups or may include at least one pixel circuit group and a single first pixel circuit. The quantity of pixel circuit groups in the display island region is not limited in this embodiment.

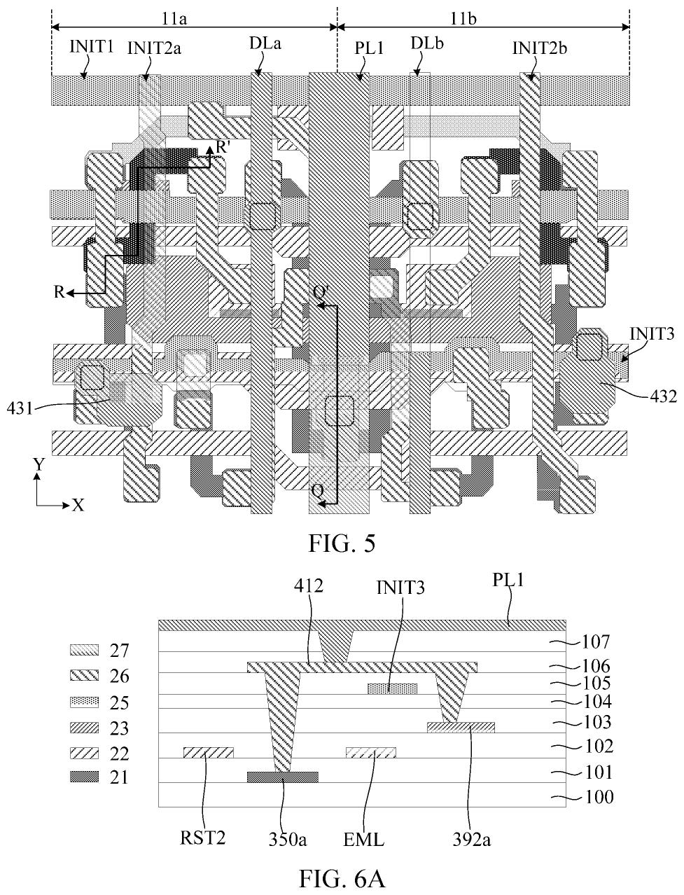

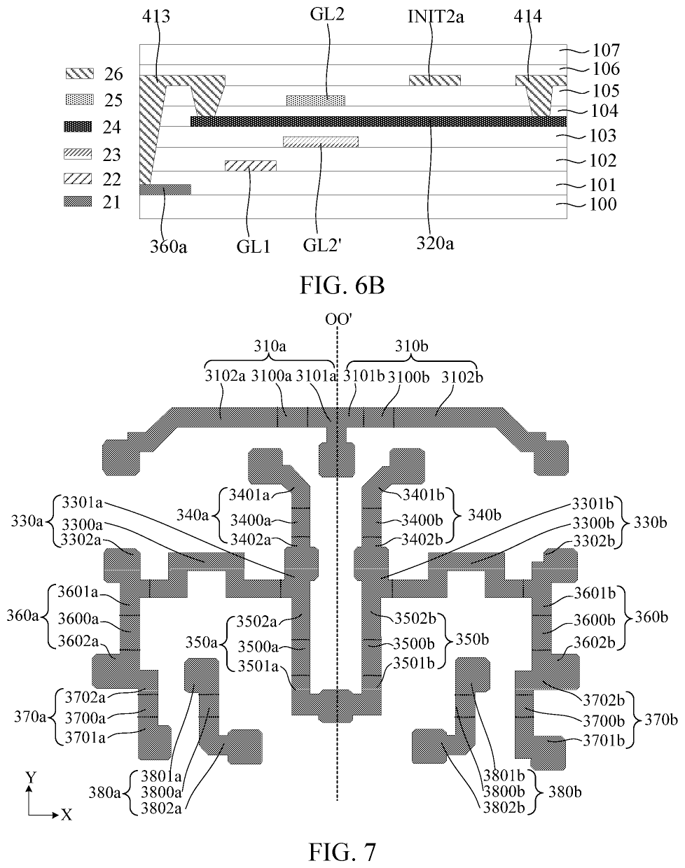

FIG. 5 is partial top view of a first display region according to at least one embodiment of the present disclosure. FIG. 5 is a schematic top view of a pixel circuit group in a display island of a first display region. FIG. 6A is a partial cross-sectional view taken along Q-Q′ direction in FIG. 5. FIG. 6B is a partial cross-sectional view taken along R-R′ direction in FIG. 5. An equivalent circuit diagram of the first pixel circuit in the pixel circuit group of this example may be as shown in FIG. 2.

In some examples, as shown in FIG. 5, in a plane parallel to the display substrate, one pixel circuit group may include first pixel circuits 11a and 11b. The first pixel circuits 11a and 11b may be arranged along the first direction X and adjacent to each other. The first pixel circuits 11a and 11b may be respectively located on two sides of the first power supply line PL1 and may be substantially symmetrical with respect to the first power supply line PL1. For example, the first transistor to the sixth transistor and the eighth transistor of the first pixel circuit 11a may be symmetrical with the first transistor to the sixth transistor and the eighth transistor of the first pixel circuit 11b with respect to the first power supply line PL1. The seventh transistor of the first pixel circuit 11a and the seventh transistor of the first pixel circuit 11b are not completely symmetrical with respect to the first power supply line PL1, and they have similar shapes but some differences. The first pixel circuits 11a and 11b are arranged to be in a mirror image structure with respect to the first power supply line PL1, which may save the space occupied by the first pixel circuits to improve the light transmittance of the first display region.

In some examples, as shown in FIGS. 6A and 6B, in a direction perpendicular to the display substrate, the display substrate may include a base substrate 100 and a circuit structure layer arranged on the base substrate 100. A transparent connection layer (e.g. including a transparent connection line connecting a first pixel circuit of an adjacent display island region), a light emitting structure layer, and an encapsulation structure layer are also provided on a side of the circuit structure layer away from the base substrate 100. The circuit structure layer may include a first semiconductor layer 21, a first conductive layer 22 (or a first gate metal layer), a second conductive layer 23 (or a second gate metal layer), a second semiconductor layer 24, a third conductive layer 25 (or a third gate metal layer), a fourth conductive layer 26 (or a first source-drain metal layer), and a fifth conductive layer 27 (or a second source-drain metal layer) arranged sequentially on the base substrate 100. A first insulation layer 101 (or a first gate insulation layer) is arranged between the first semiconductor layer 21 and the first conductive layer 22. A second insulation layer 102 (or a second gate insulation layer) is arranged between the first conductive layer 22 and the second conductive layer 23. A third insulation layer 103 (or a third gate insulation layer) is arranged between the second conductive layer 23 and the second semiconductor layer 24. A fourth insulation layer 104 (or a fourth gate insulation layer) is arranged between the second semiconductor layer 24 and the third conductive layer 25. A fifth insulation layer 105 (or an interlayer insulation layer) is arranged between the third conductive layer 25 and the fourth conductive layer 26. A sixth insulation layer 106 (or a passivation layer) and a seventh insulation layer 107 (or a first planarization layer) are arranged between the fourth conductive layer 26 and the fifth conductive layer 27. In some examples, the first insulation layer 101 to the sixth insulation layer 106 may be inorganic insulation layers, and the seventh insulation layer 107 may be an organic insulation layer. However, this embodiment is not limited thereto.

In some examples, the light emitting structure layer may at least include an anode layer, a pixel definition layer, an organic light emitting layer, and a cathode layer that are sequentially arranged on the circuit structure layer. The anode layer may be electrically connected with a pixel circuit of the circuit structure layer, the organic light emitting layer may be connected with the anode layer, the cathode layer may be connected with the organic light emitting layer, and the organic light emitting layer may emit light of corresponding colors under drive of the anode layer and the cathode layer. The encapsulation structure layer may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer may be arranged between the first encapsulation layer and the third encapsulation layer to form a laminated structure of inorganic material/organic material/inorganic material, which may ensure that external moisture cannot enter the light emitting structure layer. In some possible implementations, the display substrate may include other film layers, such as a touch structure layer, and a color filter layer, which is not limited here in this embodiment.

A structure of the display substrate will be described below through an example of a manufacturing process of the display substrate. A “patterning process” mentioned in the embodiments of the present disclosure includes a treatment such as photoresist coating, mask exposure, development, etching, and photoresist stripping for a metal material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a material on a base substrate by using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process.

“A and B are arranged in a same layer” in this specification means that A and B are formed simultaneously through a same patterning process or that distances between surfaces of A and B close to a base substrate and the base substrate are substantially the same, or that the surfaces of A and B close to the base substrate are in direct contact with a same film layer. A “thickness” of a film layer is a dimension of the film layer in a direction perpendicular to the display substrate. In this specification, “an orthographic projection of B being located within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In some exemplary implementations, a manufacturing process of the display substrate may include following operations.

(1) A base substrate is provided. In some examples, the base substrate 100 may be a rigid substrate, or may be a flexible substrate. For example, the rigid base substrate may be made of, but not limited to, one or more of glass and quartz. The flexible base substrate may be made of, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In some examples, the flexible base may include a first flexible material layer, a first inorganic material layer, a second flexible material layer and a second inorganic material layer which are stacked. The first flexible material layer and the second flexible material layer may be made of a material such as polyimide (PI), polyethylene terephthalate (PET), or a polymer soft film on which surface treatment is performed, and materials of the first inorganic material layer and the second inorganic material layer may be silicon nitride (SiNₓ) or silicon oxide (SiOₓ), etc., which are used to improve resistance to water and oxygen of the base substrate.

(2) A first semiconductor layer is formed. In some examples, a first semiconductor thin film is deposited on the base substrate 100, and the first semiconductor thin film is patterned through a patterning process to form the first semiconductor layer arranged on the base substrate. In some examples, a material of the first semiconductor layer may be amorphous silicon (a-Si), polycrystalline silicon (p-Si), hexathiophene or polythiophene, or other materials.

FIG. 7 is a schematic partial view of a first display region after the first semiconductor layer is formed in FIG. 5. In some examples, as shown in FIGS. 5 to 7, the first semiconductor layer 21 of the first display region may include a first active layer 310a of a first transistor, a third active layer 330a of a third transistor, a fourth active layer 340a of a fourth transistor, a fifth active layer 350a of a fifth transistor, a sixth active layer 360a of a sixth transistor, a seventh active layer 370a of a seventh transistor and an eighth active layer 380a of an eighth transistor of one first pixel circuit 11a in the pixel circuit group, and a first active layer 310b of a first transistor, a third active layer 330b of a third transistor, a fourth active layer 340b of a fourth transistor, a fifth active layer 350b of a fifth transistor, a sixth active layer 360b of a sixth transistor, a seventh active layer 370b of a seventh transistor and an eighth active layer 380b of an eighth transistor of another first pixel circuit 11b in the pixel circuit group.

In some examples, as shown in FIG. 7, the first active layer 310a of the first transistor of the first pixel circuit 11a and the first active layer 310b of the first transistor of the first pixel circuit 11b may be symmetrical about a first centerline OO′. The first active layer 310a of the first transistor of the first pixel circuit 11a and the first active layer 310b of the first transistor of the first pixel circuit 11b may be of an integral structure. The first active layer 310a of the first transistor of the first pixel circuit 11a and the first active layer 310b of the first transistor of the first pixel circuit 11b may extend along the first direction X and are located on a side of the third active layers 330a and 330b away from the eighth active layers 380a and 380b in the second direction Y.

In some examples, as shown in FIG. 7, the third transistor 330a of the third transistor to the sixth active layer 360a of the sixth transistor and the eighth active layer 380a of the eighth transistor of the first pixel circuit 11a, and the third active layer 330b of the third transistor to the sixth active layer 360b of the sixth transistor and the eighth active layer 380b of the eighth transistor of the first pixel circuit 11b may be symmetrical with respect to a first centerline OO′ . . . . The seventh active layer 370a of the seventh transistor of the first pixel circuit 11a and the seventh active layer 370b of the seventh transistor of the second pixel circuit 11b are not completely symmetrical with respect to the first centerline OO′, and their shapes may be similar. The third active layer 330a of the third transistor, the fourth active layer 340a of the fourth transistor, the fifth active layer 350a of the fifth transistor, the sixth active layer 360 of the sixth transistor, and the seventh active layer 370a of the seventh transistor of the first pixel circuit 11a may be of an integrated structure. The third active layer 330b of the third transistor, the fourth active layer 340b of the fourth transistor, the fifth active layer 350b of the fifth transistor, the sixth active layer 360b of the sixth transistor, and the seventh active layer 370b of the seventh transistor of the first pixel circuit 11b may be of an integrated structure. The fifth active layer 350a of the fifth transistor of the first pixel circuit 11a and the fifth active layer 350b of the fifth transistor of the first pixel circuit 11b may be of an integral structure. In the first pixel circuit 11a, the eighth active layer 380a of the eighth transistor may be located on a side of the seventh active layer 370a of the seventh transistor close to the fifth active layer 350a of the fifth transistor. The eighth active layer 380b of the eighth transistor of the first pixel circuit 11b may be located on a side of the seventh active layer 370b of the seventh transistor close to the fifth active layer 350b of the fifth transistor.

In some examples, as shown in FIG. 7, shapes of the third active layers 330a and 330b may be n-shaped, and shapes of the fourth active layers 340a and 340b, the fifth active layers 350a and 350b, and the eighth active layers 380a and 380b may be L-shaped. Shapes of the sixth active layers 360a and 360b and the seventh active layers 370a and 370b may be substantially I-shaped. However, this embodiment is not limited thereto.

In some examples, as shown in FIG. 7, the first active layer 310a of the first pixel circuit 11a may include a channel region 3100a, and a first region 3101a and a second region 3102a located on opposite sides of the channel region 3100a. The first active layer 310b of the first pixel circuit 11b may include a channel region 3100b, and a first region 3101b and a second region 3102b located on opposite sides of the channel region 3100b. The first region 3101a of the first active layer 310a and the first region 3101b of the first active layer 310b may be connected to each other.

In some examples, as shown in FIG. 7, the third active layer 330a of the first pixel circuit 11a may include a channel region 3300a, and a first region 3301a and a second region 3302a located on opposite sides of the channel region 3300a. The fourth active layer 340a may include a channel region 3400a, and a first region 3401a and a second region 3402a located on opposite sides of the channel region 3400a. The fifth active layer 350a may include a channel region 3500a, and a first region 3501a and a second region 3502a located on opposite sides of the channel region 3500a. The sixth active layer 360a may include a channel region 3600a, and a first region 3601a and a second region 3602a located on opposite sides of the channel region 3600a. The seventh active layer 370a may include a channel region 3700a, and a first region 3701a and a second region 3702a located on opposite sides of the channel region 3700a. The eighth active layer 380a may include a channel region 3800a, and a first region 3801a and a second region 3802a located on opposite sides of the channel region 3800a. The first region 3301a of the third active layer 330a, the second region 3402a of the fourth active layer 340a, and the second region 3502a of the fifth active layer 350a may be connected to each other. The second region 3302a of the third active layer 330a, and the first region 3601a of the sixth active layer 360a may be connected to each other. The second region 3602a of the sixth active layer 360a, and the second region 3702a of the seventh active layer 370a may be connected to each other.

In some examples, as shown in FIG. 7, the third active layer 330b of the first pixel circuit 11b may include a channel region 3300b, and a first region 3301b and a second region 3302b located on opposite sides of the channel region 3300b. The fourth active layer 340b may include a channel region 3400b, and a first region 3401b and a second region 3402b located on opposite sides of the channel region 3400b. The fifth active layer 350b may include a channel region 3500b, and a first region 3501b and a second region 3502b located on opposite sides of the channel region 3500b. The sixth active layer 360b may include a channel region 3600b, and a first region 3601b and a second region 3602b located on opposite sides of the channel region 3600b. The seventh active layer 370b may include a channel region 3700b, and a first region 3701b and a second region 3702b located on opposite sides of the channel region 3700b. The eighth active layer 380b may include a channel region 3800b, and a first region 3801b and a second region 3802b located on opposite sides of the channel region 3800b. The first region 3301b of the third active layer 330b, the second region 3402b of the fourth active layer 340b, and the second region 3502b of the fifth active layer 350b may be connected to each other. The second region 3302b of the third active layer 330b, and the first region 3601b of the sixth active layer 360b may be connected to each other. The second region 3602b of the sixth active layer 360b, and the second region 3702b of the seventh active layer 370b may be connected to each other. The first region 3501a of the fifth active layer 350a of the first pixel circuit 11a, and the first region 3501b of the fifth active layer 350b of the first pixel circuit 11b may be connected to each other.

(3) Forming a first conductive layer. In some examples, a first insulation thin film and a first conductive thin film are deposited sequentially on the base substrate on which the aforementioned structures are formed, and the first conductive thin film is patterned through a patterning process to form a first insulation layer and a first conductive layer arranged on the first insulation layer.

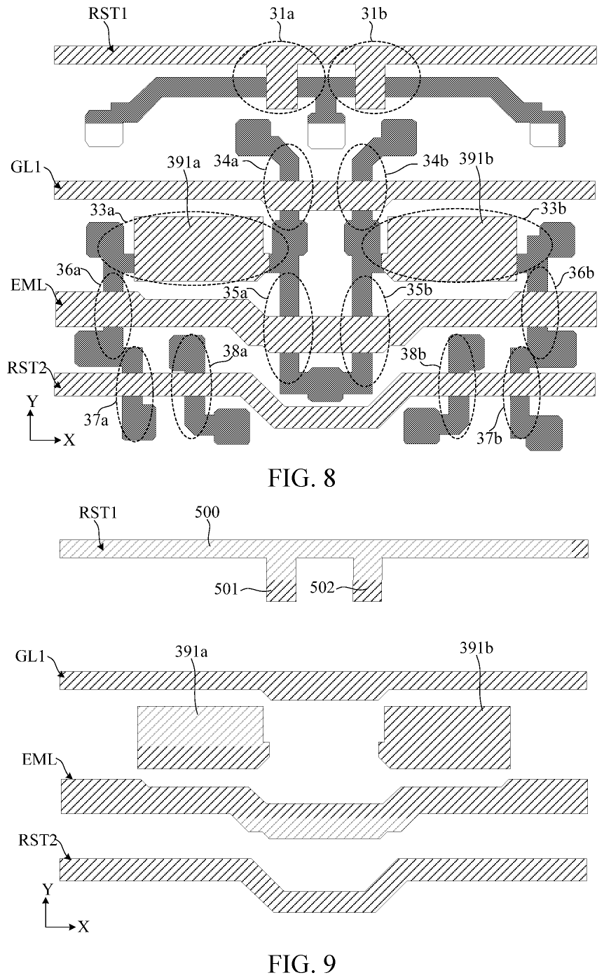

FIG. 8 is a schematic partial view of a first display region after the first conductive layer is formed in FIG. 5. FIG. 9 is a schematic diagram of the first conductive layer in FIG. 8. In some examples, as shown in FIGS. 5 to 9, the first conductive layer 22 of the first display region may include a first scan line GL1, a light emitting control line EML, a first reset control line RST1, a second reset control line RST2, a first electrode 391a of a storage capacitor and gates of a plurality of first type transistors (e.g. including a gate of a first transistor 31a, gates of a third transistors 33a to an eighth transistors 38a) of the first pixel circuit 11a, a first electrode 391b of a storage capacitor and gates of a plurality of first type transistors (e.g. including a gate of the first transistor 31b, gates of a third transistors 33b to an eighth transistors 38b) of the first pixel circuit 11b.

In some examples, as shown in FIGS. 8 and 9, the first scan line GL1, the light emitting control line EML, the first reset control line RST1, and the second reset control line RST2 may all extend along the first direction X. The first scan line GL1 may be located between the first reset control line RST1 and the light emitting control line EML in the second direction Y and the second reset control line RST2 may be located on a side of the light emitting control line EML away from the first scan line GL1.

In some examples, as shown in FIG. 5, FIG. 7 to FIG. 9, the gate of the first transistor 31a, the gate of the first transistor 31b and the first reset control line RST1 may be of an integral structure. The first reset control line RST1 may be located on a side of the first active layer 310a of the first transistor 31a away from the third transistors 33a and 33b in the second direction Y. As shown in FIG. 9, the first reset control line RST1 may include a first main body 500 extending along the first direction X, a first bump 501 protruding from the first main body 500 along the second direction Y toward the first active layer 310a of the first transistor 31a, and a second bump 502 protruding from the first main body 500 along the second direction Y toward the first active layer 310b of the first transistor 31b. An orthographic projection of the first bump 501 on the base substrate may be overlapped with an orthographic projection of the channel region 3100a of the first active layer 310a of the first transistor 31a on the base substrate, and an orthographic projection of the second bump 502 on the base substrate may be overlapped with an orthographic projection of the channel region 3100b of the first active layer 310b of the first transistor 31b on the base substrate. For example, the first bump 501 and the second bump 502 may be rectangular. The first bump 501 may serve as a gate of the first transistor 31a, and the second bump 502 may serve as a gate of the second transistor 31b. Arrangement mode of the first transistors in this example may reduce sizes of the first pixel circuits 11a and 11b along the second direction Y, thereby saving the space occupied by the pixel circuits.

In some examples, as shown in FIG. 5 and FIG. 9B, the gate of the third transistor 33a of the first pixel circuit 11a and the first electrode 391a of the storage capacitor of the first pixel circuit 11a may be of an integral structure. The gate of the third transistor 33b of the first pixel circuit 11b, and the first electrode 391b of the storage capacitor of the first pixel circuit 11b may be of an integrated structure.

In some examples, as shown in FIG. 8 and FIG. 9, the gate of the fourth transistor 34a, the gate of the fourth transistor 34b, and the first scan line GL1 may be of an integral structure. The gate of the fifth transistor 35a, the gate of the fifth transistor 35b, the gate of the sixth transistor 36a, the gate of the sixth transistor 36b, and the light emitting control line EML may be of an integral structure. The gate of the seventh transistor 37a, the gate of the seventh transistor 37b, the gate of the eighth transistor 38a, the gate of the eighth transistor 38b, and the second reset control line RST2 may be of an integral structure.

In some examples, after the first conductive layer is formed, the first conductive layer may be used as a shield to perform a conductive treatment on the first semiconductor layer. A region of the first semiconductor layer, which is shielded by the first conductive layer, forms channel regions of the plurality of transistors, and a region of the first semiconductor layer, which is not shielded by the first conductive layer, is made to be conductive, that is, all of the first regions and the second regions of the active layers of the first type transistors are made to be conductive.

(4) A second conductive layer is formed. In some examples, a second insulation thin film and a second conductive thin film are deposited sequentially on the base substrate on which the aforementioned structures are formed, and the second conductive thin film is patterned through a patterning process to form a second insulation layer and a second conductive layer arranged on the second insulation layer.

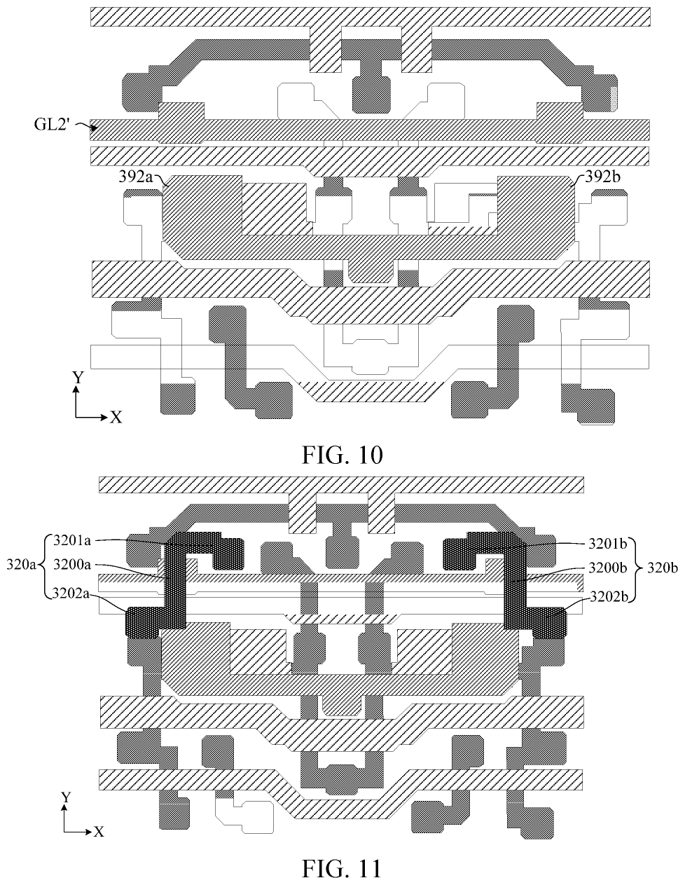

FIG. 10 is a schematic partial view of a first display region after the second conductive layer is formed in FIG. 5. In some examples, as shown in FIGS. 5 to 10, the second conductive layer 23 of the first display region may include a second electrode 392a of the storage capacitor of the first pixel circuit 11a, a second electrode 392b of the storage capacitor of the first pixel circuit 11b, and a second scan auxiliary line GL2′. The second scan auxiliary line GL2′ may extend along the first direction X. An orthographic projection of the second scan auxiliary line GL2′ on the base substrate may be located on a side of an orthographic projection of the first scan line GL1 on the base substrate close to the first transistor. The orthographic projection of the second scan auxiliary line GL2′ on the base substrate may not be overlapped with the orthographic projection of the first scan line GL1 on the base substrate.

In some examples, as shown in FIGS. 8 and 10, an orthographic projection of the second electrode 392a of the storage capacitor of the first pixel circuit 11a on the base substrate and an orthographic projection of the first electrode 391a of the storage capacitor of the first pixel circuit 11a on the base substrate may be overlapped, and an orthographic projection of the second electrode 392b of the first electrode 391b of the storage capacitor on the base substrate and an orthographic projection of the first electrode 391b of the storage capacitor of the first pixel circuit 11b on the base substrate may be overlapped. The second electrode 392a of the storage capacitor of the first pixel circuit 11a and the second electrode 392b of the storage capacitor of the first pixel circuit 11b may be of an integral structure. For example, a shape of the integral structure may be substantially U-shaped.

(5) A second semiconductor layer is formed. In some examples, a third insulation thin film and a second semiconductor thin film are sequentially deposited on the base substrate on which the aforementioned patterns are formed, and the second semiconductor thin film is patterned through a patterning process to form a third insulation layer and a second semiconductor layer arranged on the third insulation layer. In some examples, a material of the second semiconductor layer may be IGZO.

FIG. 11 is a schematic partial view of a first display region after the second semiconductor layer is formed in FIG. 5. In some examples, as shown in FIGS. 5 to 11, the second semiconductor layer 24 of the first display region may include active layers of the second type transistors of the first pixel circuits 11a and 11b (e.g., a second active layer 320a of the second transistor of the first pixel circuit 11a, a second active layer 320b of the second transistor of the first pixel circuit 11b). The second active layer 320a may include a channel region 3200a, and a first region 3201a and a second region 3202a located on opposite sides of the channel region 3200a. The second active layer 320b may include a channel region 3200b, and a first region 3201b and a second region 3202b located on opposite sides of the channel region 3200b. The orthographic projection of the second scan auxiliary line GL2′ on the base substrate may cover orthographic projections of the channel region 3200a of the second active layer 320a and the channel region 3200b of the second active layer 320b on the base substrate. The second scan auxiliary line GL2′ may be used as a bottom gate of a second transistor and may also shield the channel region of the second transistor to avoid affecting performance of the second transistor.

(6) A third conductive layer is formed. In some examples, a fourth insulation thin film and a third conductive thin film are sequentially deposited on the base substrate on which the aforementioned patterns are formed, and the third conductive thin film is patterned through a patterning process to form a fourth insulation layer and a third conductive layer arranged on the fourth insulation layer.

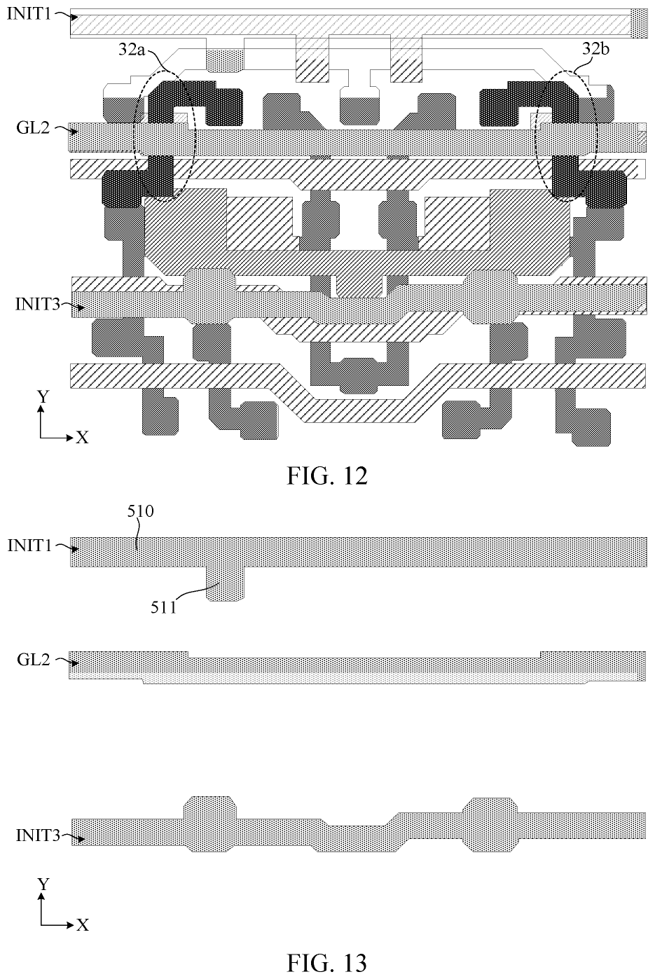

FIG. 12 is a schematic partial view of a first display region after the third conductive layer is formed in FIG. 5. FIG. 13 is a schematic diagram of the third conductive layer in FIG. 12. In some examples, as shown in FIGS. 5 to 13, the third conductive layer 25 of the first display region may include gates of the second type transistors of the first pixel circuit (including, for example, a gate of the second transistor 32a, a gate of the second transistor 32b), a second scan line GL2, a first initial signal line INIT1, and a third initial signal line INIT3. Herein, the second scan line GL2, the first initial signal line INIT1, and the third initial signal line INIT3 may all extend along the first direction X. An orthographic projection of the second scan line GL2 on the base substrate may be overlapped with the orthographic projection of the second scan auxiliary line GL2′ on the base substrate. The gate of the second transistor 32a, the gate of the second transistor 32b, and the second scan line GL2 may be of an integral structure. For example, the second scan line GL2 and the second scan auxiliary line GL2′ may be configured to transmit a second scan signal. The second scan line GL2 and the second scan auxiliary line GL2′ may be electrically connected in a peripheral region. However, this embodiment is not limited thereto.

In some examples, as shown in FIGS. 8 to 13, the first initial signal line INIT1 may include a second main body 510 extending along the first direction X, and a third bump 511 extending from the second main body 510 along the second direction Y toward the second scan line GL2. An orthographic projection of the third bump 511 on the base substrate may not be overlapped with orthographic projections of the first bump 501 and the second bump 502 of the first reset control line RST1 on the base substrate, and the third bump 511 may be located on a side of the first bump 501 away from the second bump 502 in the first direction X. An orthographic projection of the second main body 510 of the first initial signal line INIT1 may be overlapped with an orthographic projection of the first main body 500 of the first reset control line RST1 on the base substrate, for example, the orthographic projection of the second main body 510 on the base substrate may cover the orthographic projection of the first main body 500 on the base substrate. In this example, the first initial signal line INIT1 is overlapped with the first reset control line RST1, which may save space occupied by the traces and is beneficial to improving the light transmittance of the first display region.

In some examples, as shown in FIGS. 8 to 13, an orthographic projection of the third initial signal line INIT3 on the base substrate may be overlapped with an orthographic projection of the light emitting control line EML on the base substrate. In this example, the aforementioned first signal line may be the light emitting control line EML. In this example, the third initial signal line INIT3 is overlapped with the light emitting control line EML, which may save the space occupied by the traces and is beneficial to improving the light transmittance of the first display region. However, this embodiment is not limited thereto. In some other examples, the first signal line may be the second reset control line RST2. An orthographic projection of the third initial signal line on the base substrate may be overlapped with an orthographic projection of the second reset control line on the base substrate.

(7) A fifth insulation layer is formed. In some examples, a fifth insulation thin film is deposited on the base substrate on which the aforementioned patterns are formed, and the fifth insulation thin film is patterned through a patterning process to form a fifth insulation layer.

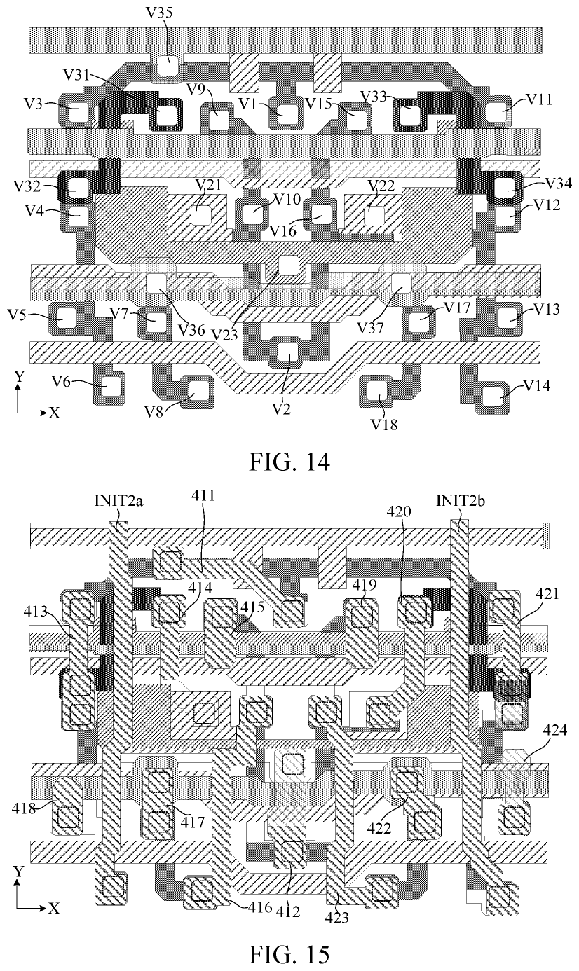

FIG. 14 is a schematic partial view of a first display region after a fifth insulation layer is formed in FIG. 5. In some examples, as shown in FIGS. 5 to 14, the fifth insulation layer 105 of the first display region may be provided with a plurality of via holes, which may include, for example, first type via holes exposing a surface of the first semiconductor layer 21, second type via holes exposing a surface of the first conductive layer 22, third type via hole exposing a surface of the second conductive layer 23, fourth type via holes exposing a surface of the second semiconductor layer 24, and fifth type via hole exposing a surface of the third conductive layer 25. For example, the fourth type via holes and the fifth type via holes may be formed by a same patterning process in one time, and the first type via holes, the second type via holes, and the third type via holes may be formed by a same patterning process in one time.

In some examples, the fifth insulation layer 105, the fourth insulation layer 104, the third insulation layer 103, the second insulation layer 102 and the first insulation layer 101 in the first type via holes may be removed, for example, the first type via holes may include a first via hole V1 to an eighteenth via hole V18. The fifth insulation layer 105, the fourth insulation layer 104, the third insulation layer 103, and the second insulation layer 102 in the second type via holes may be removed, for example, the second type via holes may include a twenty-first via hole V21 and a twenty-second via hole V22. The fifth insulation layer 105, the fourth insulation layer 104, and the third insulation layer 103 in the third type via hole may be removed, for example, the third type via hole may include a twenty-third via hole V23. The fifth insulation layer 105 and the fourth insulation layer 104 in the fourth type via holes may be removed, for example, the fourth type via holes may include a thirty-first via hole V31 to a thirty-fourth via hole V34. The fifth insulation layer 105 in the fifth type via holes may be removed, for example, the fifth type via holes may include a thirty-fifth via hole V35 to a thirty-seventh via hole V37. The thirty-fifth via hole V35 may expose a surface of the third bump 511 of the first initial signal line INIT1. The thirty-sixth via hole V36 and the thirty-seventh via hole V37 may expose a surface of the third initial signal line INIT3.

(8) A fourth conductive layer is formed. In some examples, a fourth conductive thin film is deposited on the base substrate on which the aforementioned patterns are formed, and the fourth insulation thin film is patterned through a patterning process to form a fourth conductive layer on the fifth insulation layer.

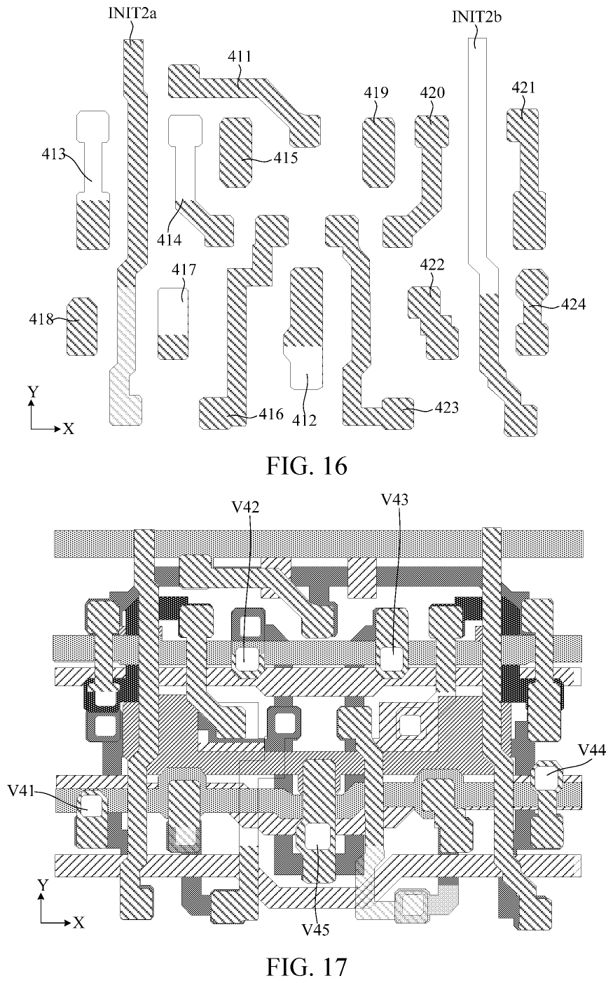

FIG. 15 is a schematic partial view of a first display region after a fourth conductive layer is formed in FIG. 5. FIG. 16 is a schematic diagram of the fourth conductive layer in FIG. 15. In some examples, as shown in FIGS. 5 to 16, the fourth conductive layer 26 of the first display region may include second initial signal lines INIT2a and INIT2b, and a plurality of connection electrodes (including, for example, a first connection electrode 411 to a fourteenth connection electrode 424).

In some examples, as shown in FIGS. 5 to 16, the second initial signal lines INIT2a and INIT2b may both extend along the second direction Y. The second initial signal line INIT2a may be electrically connected to the first region 3701a of the seventh active layer 370a of the seventh transistor 37a of the first pixel circuit 11a through the sixth via hole V6. The second initial signal line INIT2b may be electrically connected to the first region 3701b of the seventh active layer 370b of the seventh transistor 37b of the first pixel circuit 11b through the fourteenth via hole V14. In this example, the second initial signal lines INIT2a and INIT2b may extend along the second direction Y and are not communicated in the first direction X, which may reduce the quantity of traces extending along the first direction X, which facilitates saving space.

In some examples, as shown in FIGS. 5 to 16, the first connection electrode 411 may be electrically connected with the first region 3101a of the first active layer 310a of the first transistor 31a of the first pixel circuit 11a through the first via hole V1, and may also be electrically connected with the first initial signal line INIT1 through the thirty-fifth via hole V35. In this example, the first active layer 310a of the first transistor 31a of the first pixel circuit 11a and the first active layer 310b of the first transistor 31b of the first pixel circuit 11b are of an integral structure, and the first initial signal line INIT1 may be electrically connected with the first pixel circuits 11a and 11b simultaneously by using the first connection electrode 411. The second connection electrode 412 may be electrically connected to the first region 3501a of the fifth active layer 350a of the fifth transistor 35a of the first pixel circuit 11a through the second via hole V2, and may also be electrically connected to the second electrode 392a of the storage capacitor of the first pixel circuit 11a through the twenty-third via hole V23. In this example, the fifth active layer 350a of the fifth transistor 35a of the first pixel circuit 11a and the fifth active layer 350b of the fifth transistor 35b of the first pixel circuit 11b are of an integral structure, the second electrodes 392a and 392b of the storage capacitor are of an integral structure, and the first power supply line may be electrically connected with the first pixel circuits 11a and 11b simultaneously by using the second connection electrode. The third connection electrode 413 may be electrically connected to the second region 3102a of the first active layer 310a of the first transistor 31a of the first pixel circuit 11a through the third via hole V3, may also be electrically connected to the first region 3601a of the sixth active layer 360a of the sixth transistor 36a through the fourth via hole V4, and may also be electrically connected to the second region 3202a of the second active layer 320a of the second transistor 32a through the thirty-second via hole V32. The fourth connection electrode 414 may be electrically connected with the first region 3201a of the second active layer 320a of the second transistor 32a through the thirty-first via hole V31, and may also be electrically connected with the gate of the third transistor 33a through the twenty-first via hole V21. The fifth connection electrode 415 may be electrically connected to the first region 3401a of the fourth active layer 340a of the fourth transistor 34a through the ninth via hole V9. The sixth connection electrode 416 may be electrically connected to the second region 3402a of the fourth active layer 340a of the fourth transistor 34 through the tenth via hole V10, and may also be electrically connected to the second region 3802a of the eighth active layer 380a of the eighth transistor 38a through the eighth via hole V8. The seventh connection electrode 417 may be electrically connected to the first region 3801a of the eighth active layer 380a of the eighth transistor 38a through the seventh via hole V7, and may also be electrically connected to the third initial signal line INIT3 through the thirty-sixth via hole V36. The eighth connection electrode 418 may be electrically connected to the second region 3602a of the sixth active layer 360a of the sixth transistor 36a through the fifth via hole V5. The ninth connection electrode 419 may be electrically connected to the first region 3401b of the fourth active layer 340b of the fourth transistor 34b of the first pixel circuit 11b through the fifteenth via hole V15. The tenth connection electrode 420 may be electrically connected to the gate of the third transistor 33b of the first pixel circuit 11b through the twenty-second via hole V22, and may also be electrically connected to the first region 3201b of the second active layer 320b of the second transistor 32b through the thirty-third via hole V33. The eleventh connection electrode 421 may be electrically connected to the second region 3102b of the first active layer 310b of the first transistor 31b through the eleventh via hole V11, may also be electrically connected to the first region 3601b of the sixth active layer 360b of the sixth transistor 36b through the twelfth via hole V12, and may also be electrically connected to the second region 3202b of the second active layer 320b of the second transistor 32b through the thirty-fourth via hole V34. The twelfth connection electrode 422 may be electrically connected to the first region 3801b of the eighth active layer 380b of the eighth transistor 38b through the seventeenth via hole V17, and may also be electrically connected to the third initial signal line INIT3 through the thirty-seventh via hole V37. The thirteenth connection electrode 423 may be electrically connected to the second region 3802b of the eighth active layer 380b of the eighth transistor 38b through the eighteenth via hole V18, and may also be electrically connected to the second region 3402b of the fourth active layer 340b of the fourth transistor 34b through the sixteenth via hole V16. The fourteenth connection electrode 424 may be electrically connected to the second region 3602b of the sixth active layer 360b of the sixth transistor 36b through the thirteenth via hole V13.

In this example, the eighth transistor 38a of the first pixel circuit 11a may be electrically connected with the third initial signal line INIT3 by using the seventh connection electrode 417, and the eighth transistor 38b of the first pixel circuit 11b may be electrically connected with the third initial signal line INIT3 by using the twelfth connection electrode 422. Orthographic projections of the seventh connection electrode 417 and the twelfth connection electrode 422 on the base substrate are located on a side of the second reset control line RST2 close to the third transistor, that is, a connection position of the eighth transistor and the third initial signal line INIT3 is located on a side of the second reset control line RST2 close to the third transistor. In this way, a size of the first pixel circuit along the second direction Y may be reduced, thereby facilitating the improvement of the light transmittance of the first display region.

(9) A sixth insulation layer and a seventh insulation layer are formed. In some examples, a sixth insulation thin film is deposited on the base substrate on which the aforementioned patterns are formed, and then a seventh insulation thin film is coated, and the seventh insulation thin film and the sixth insulation thin film are patterned through a patterning process to form a sixth insulation layer and a seventh insulation layer.

FIG. 17 is a schematic partial view of a first display region after a seventh insulation layer is formed in FIG. 5. In some examples, as shown in FIG. 5 to FIG. 17, the seventh insulation layer 107 of the first display region may be provided with a plurality of via holes, which may include, for example, a forty-first via hole V41 to a forty-fifth via hole V45. The seventh insulation layer 107 and the sixth insulation layer 106 in the forty-first via hole V41 to the forty-fifth via hole V45 may be removed. The forty-first via hole V41 may expose a surface of the eighth connection electrode 418, the forty-second via hole V42 may expose a surface of the fifth connection electrode 415, the forty-third via hole V43 may expose a surface of the ninth connection electrode 419, the forty-fourth via hole V44 may expose a surface of the fourteenth connection electrode 424, and the forty-fifth via hole V45 may expose a surface of the second connection electrode 412.

(10) A fifth conductive layer is formed. In some examples, a fifth conductive thin film is deposited on the base substrate on which the aforementioned patterns are formed, and the fifth conductive thin film is patterned through a patterning process to form a fifth conductive layer on the seventh insulation layer.

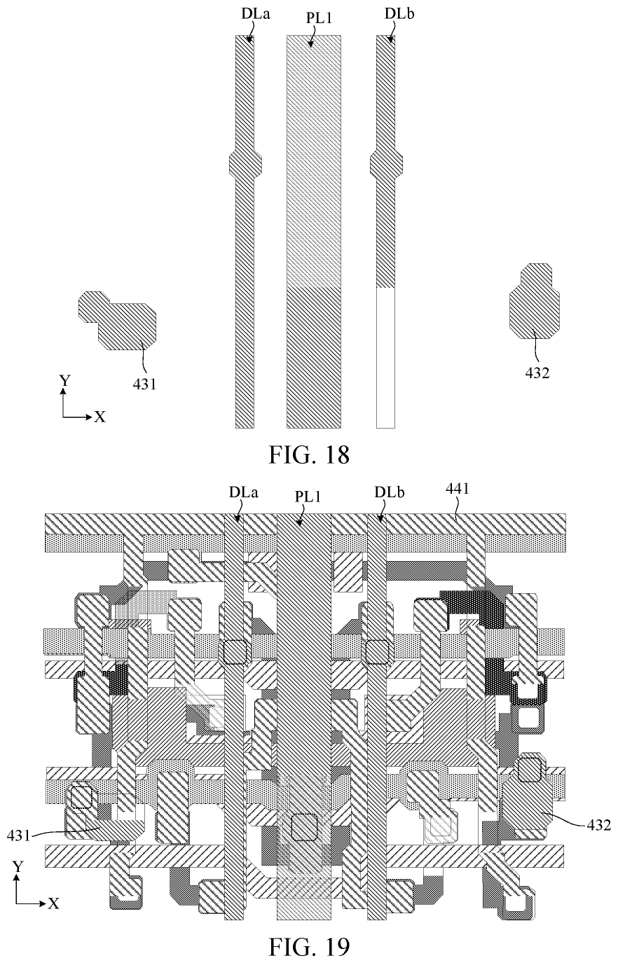

FIG. 18 is a schematic diagram of the fifth conductive layer in FIG. 5. In some examples, as shown in FIGS. 5 to 18, the fifth conductive layer 27 of the first display region may include a first power supply line PL1, a first data line DLa, a second data line DLb, a first anode connection electrode 431, and a second anode connection electrode 432. The first power supply line PL1 may be electrically connected with the second connection electrode 412 through the forty-fifth via hole V45, so that a first voltage signal is provided to the first pixel circuits 11a and 11b. The first data line DLa may be electrically connected with the fifth connection electrode 415 through the forty-second via hole V42, so that a data signal is provided to the first pixel circuit 11a. The second data line DLb may be electrically connected with the ninth connection electrode 419 through the forty-third via hole V43, so that a data signal is provided to the first pixel circuit 11b. The first anode connection electrode 431 may be electrically connected with the eighth connection electrode 418 through the forty-first via hole V41 and the first anode connection electrode 431 may subsequently be electrically connected with an anode of a first light emitting element. The second anode connection electrode 432 may be electrically connected with the fourteenth connection electrode 424 through the forty-fourth via hole V44 and the second anode connection electrode 432 may subsequently be electrically connected with the anode of the first light emitting element.

In some examples, as shown in FIG. 18, the first data line DLa and the second data line DLb may be located on opposite sides of the first power supply line PL1 along the first direction X. The first data line DLa and the first power supply line PL1 may be adjacent, and the second data line DLb and the first power supply line PL1 may be adjacent.

(11) An eighth insulation layer, a transparent connection layer, a light emitting structure layer and an encapsulation structure layer are formed sequentially.

In some examples, an eighth insulation thin film is coated on the base substrate on which the aforementioned patterns are formed, and the eighth insulation thin film is patterned through a patterning process to form an eighth insulation layer. Subsequently, a transparent conductive layer is deposited, and a transparent connection layer is formed through a patterning process, which may include a transparent connection lines connecting first pixel circuits in adjacent display island regions. Subsequently, a ninth insulation thin film is coated to form a ninth insulation layer.

In some examples, an anode thin film is deposited on the base substrate on which the aforementioned patterns are formed, and the anode thin film is patterned through a patterning process to form an anode layer. Then, a pixel definition thin film is coated and a pixel definition layer is formed by masking, exposure and development processes. The pixel definition layer may be formed with a plurality of pixel openings exposing the anode layer. An organic emitting layer is formed in the pixel openings formed earlier, and the organic light emitting layer is connected with the anode layer. Subsequently, a cathode thin film is deposited, and the cathode thin film is patterned through a patterning process to form a pattern of a cathode, and the cathode is connected with the organic emitting layer. Then, an encapsulation layer is formed on the cathode. The encapsulation layer may include a stacked structure of inorganic material/organic material/inorganic material.

In some examples, the first conductive layer 22, the second conductive layer 23, the third conductive layer 25, the fourth conductive layer 26, and the fifth conductive layer 27 may be made of a metal material, such as any one or more of Argentum (Ag), Copper (Cu), Aluminum (Al) and Molybdenum (Mo), or an alloy material of the aforementioned metals, such as an Aluminum Neodymium alloy (AlNd) or a Molybdenum Niobium alloy (MoNb), and may be in a single-layer structure or a multi-layer composite structure, such as Mo/Cu/Mo. The first insulation layer 101, the second insulation layer 102, the third insulation layer 103, the fourth insulation layer 104, the fifth insulation layer 105 and the sixth insulation layer 106 may be made of any one or more of Silicon Oxide (SiOₓ), Silicon Nitride (SiNₓ), and Silicon OxyNitride (SiON), and may each be a single layer, a multi-layer, or a composite layer. The seventh insulation layer 107, the eighth insulation layer and the ninth insulation layer may be made of an organic material, such as polyimide, acrylic, or polyethylene terephthalate. The pixel definition layer may be made of an organic material, such as polyimide, acrylic, or polyethylene terephthalate. The anode layer may be made of a reflective material such as a metal, and the cathode may be made of a transparent conductive material. However, this embodiment is not limited thereto.

A structure and a manufacturing process of the display substrate of this embodiment are merely illustrative. In some exemplary implementation, a corresponding structure may be changed and a patterning process may be added or removed according to actual needs. The manufacturing process of the exemplary embodiment may be implemented using an existing mature manufacturing equipment, and may be compatible well with an existing manufacturing process, simple in process implementation, easy to implement, high in a production efficiency, low in a production cost, and high in yield.

In some exemplary implementations, the structure of the second pixel circuit in the second display region may be substantially the same as the structure of the first pixel circuit, and the structure and arrangement of the second light emitting elements in the second display region may be substantially the same as the structure and arrangement of the first light emitting elements, and thus will not be repeated here.

In some other examples, the display substrate of this embodiment may be adapted to a display substrate of a non-FDC scheme. For example, the pixel circuits of the display region of the display substrate all adopt the arrangement and layout design of the pixel circuits as in the aforementioned embodiments to improve light transmittance of the display region.

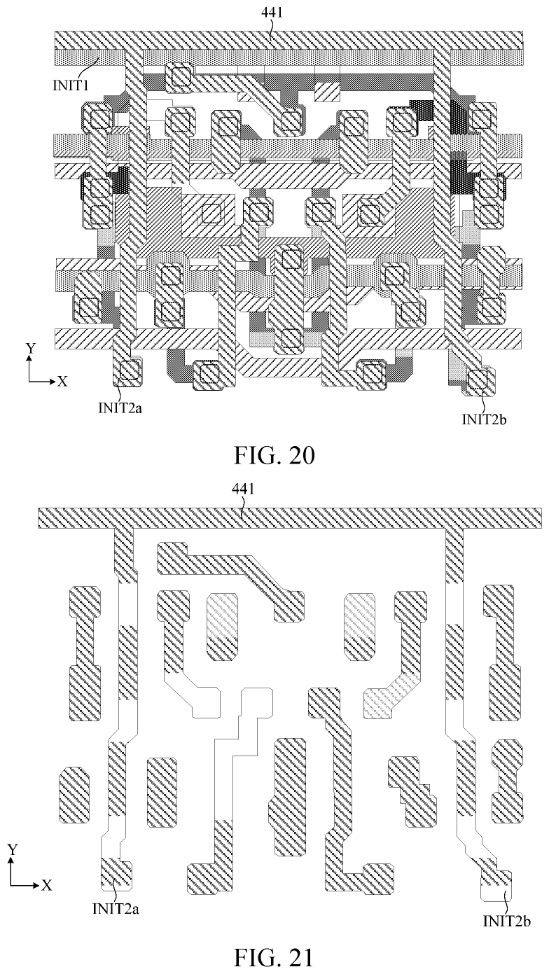

FIG. 19 is another schematic partial view of a first display region according to at least one embodiment of the present disclosure. FIG. 20 is a schematic partial view of a first display region after a fourth conductive layer is formed in FIG. 19. FIG. 21 is a schematic diagram of the fourth conductive layer in FIG. 20.

In some examples, as shown in FIGS. 19 to 21, the second initial signal lines INIT2a and INIT2b may be electrically connected to each other through an initial connection line 441 extending along the first direction X. For example, the second initial signal lines INIT2a and INIT2b, and the initial connection line 441 may be of an integral structure. A mesh structure for transmitting the second initial signal may be achieved by electrically connecting the initial connection line 441 extending along the first direction X with the second initial signal line extending along the second direction Y, thereby improving transmission stability and uniformity of the second initial signal.

In some examples, as shown in FIGS. 20 and 21, an orthographic projection of the initial connection line 441 on the base substrate may be overlapped with an orthographic projection of the first initial signal line INIT1 on the base substrate. For example, the orthographic projection of the initial connection line 441 on the base substrate may be partially overlapped with the orthographic projection of the first initial signal line INIT1 on the base substrate. In this way, the space occupied by the traces may be reduced, which is beneficial to improving the light transmittance of the first display region.

Rest of the structure of the display substrate according to this embodiment may be referred to descriptions of the aforementioned embodiments, and will not be repeated here.

At least one embodiment of the present disclosure further provides a display apparatus which includes the display substrate as described above.

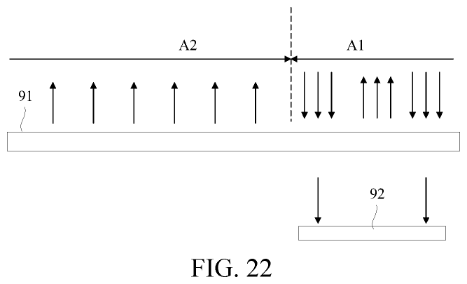

FIG. 22 is a schematic diagram of a display apparatus according to at least one embodiment of the present disclosure. As shown in FIG. 22, an embodiment provides a display apparatus, which includes a display substrate 91 and a photosensitive sensor 92 located on a light exit side of a display structure layer away from the display substrate 91. An orthographic projection of the photosensitive sensor 92 on the display substrate 91 is overlapped with the first display region A1.

In some exemplary implementations, the display substrate 91 may be a flexible OLED display substrate, a QLED display substrate, a Micro-LED display substrate or a Mini-LED display substrate. The display apparatus may be any product or component with a display function such as an OLED display, a cell phone, a tablet, a television, a display, a laptop computer, a digital photo frame, and a navigator, which is not limited in the embodiments of the present disclosure.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising:
a base substrate comprising at least a first display region;
at least one pixel circuit group located in the first display region; the pixel circuit group comprises two first pixel circuits adjacent in a first direction;
a plurality of data lines electrically connected to the at least one pixel circuit group and configured to provide a data signal to the at least one pixel circuit group, wherein the plurality of data lines comprise a first data line and a second data line;
a first power supply line electrically connected to the at least one pixel circuit group and configured to provide a power supply signal to the at least one pixel circuit group;
one first pixel circuit in the pixel circuit group is electrically connected to the first data line, and another first pixel circuit in the pixel circuit group is electrically connected to the second data line; the first data line, the second data line, and the first power supply line all extend along a second direction, and the first direction intersects with the second direction;
the first data line and the second data line are respectively located on opposite sides of the first power supply line along the first direction, and both the first data line and the second data line are adjacent to the first power supply line; and two first pixel circuits in the pixel circuit group are respectively located on two sides of the first power supply line.

2. The display substrate according to claim 1, wherein the two first pixel circuits in the pixel circuit group are substantially symmetrical with respect to the first power supply line.

3. The display substrate according to claim 1, further comprising:
a first initial signal line and a first reset control line; each first pixel circuit at least comprises a drive transistor and a first transistor, wherein a first electrode of the first transistor is electrically connected with the first initial signal line, a second electrode of the first transistor is electrically connected with a second electrode of the drive transistor, and a gate of the first transistor is electrically connected with the first reset control line; and
an active layer of the first transistor of the first pixel circuit extends along the first direction, and the gate of the first transistor extends along the second direction.

4. The display substrate according to claim 3, wherein the first reset control line extends along the first direction and is integrally formed with gates of first transistors of the two first pixel circuits of the pixel circuit group; and the first reset control line is located on a side of active layers of the first transistors of the two first pixel circuits away from the drive transistor in the second direction.

5. The display substrate according to claim 3, wherein the first initial signal line extends along the first direction, and an orthographic projection of the first initial signal line on the base substrate is overlapped with an orthographic projection of the first reset control line on the base substrate.

6. The display substrate according to claim 5, wherein the first initial signal line is located on a side of the first reset control line away from the base substrate.

7. The display substrate according to claim 3, wherein active layers of first transistors of the two first pixel circuits in the pixel circuit group are of an integral structure.

8. The display substrate according to claim 7, further comprising a first connection electrode, wherein the active layers of the first transistors of the two first pixel circuits in the pixel circuit group are electrically connected to the first connection electrode through a same first via hole, and the first connection electrode is electrically connected to the first initial signal line.

9. The display substrate according to claim 3, further comprising a plurality of second initial signal lines extending along the second direction, and the first pixel circuit is electrically connected to the second initial signal lines; a second initial signal line electrically connected to one first pixel circuit in the pixel circuit group is located on a side of the first data line away from the first power supply line, and a second initial signal line electrically connected to another first pixel circuit is located on a side of the second data line away from the first power supply line.

10. The display substrate according to claim 9, further comprising: an initial connection line extending along the first direction, wherein the initial connection line is electrically connected to the plurality of second initial signal lines, and an orthographic projection of the initial connection line on the base substrate is overlapped with an orthographic projection of the first initial signal line electrically connected to the first pixel circuits on the base substrate.

11. The display substrate according to claim 10, wherein the initial connection line and the plurality of second initial signal lines are of an integral structure, and the initial connection line is located on a side of the first initial signal line away from the base substrate.

12. The display substrate according to claim 2, wherein the first power supply line, the first data line and the second data line disposed in a same layer, and the first power supply line is located on a side of the plurality of second initial signal lines away from the base substrate.

13. The display substrate according to claim 3, further comprising a third initial signal line and a first signal line, wherein the first pixel circuit is further electrically connected to the third initial signal line and the first signal line, and both the third initial signal line and the first signal line extend along the first direction; and
an orthographic projection of the third initial signal line on the base substrate is overlapped with an orthographic projection of the first signal line on the base substrate, and the third initial signal line is located on a side of the first signal line away from the base substrate.

14. The display substrate according to claim 13, further comprising: a second reset control line; the first pixel circuit further comprises an eighth transistor, wherein a first electrode of the eighth transistor is electrically connected to the third initial signal line, a second electrode of the eighth transistor is electrically connected to a first electrode of the drive transistor, and a gate of the eighth transistor is electrically connected to the second reset control line; and
a connection position between the eighth transistor and the third initial signal line is located on a side of the second reset control line close to the drive transistor.

15. The display substrate according to claim 13, wherein the first pixel circuit further comprises a fifth transistor and a storage capacitor; a first electrode of the fifth transistor is electrically connected to the first power supply line, a second electrode of the fifth transistor is electrically connected to a first electrode of the drive transistor, and a gate of the fifth transistor is electrically connected to a light emitting control line; a first electrode of the storage capacitor is electrically connected with the gate of the drive transistor, and a second electrode of the storage capacitor is electrically connected with the first power supply line; and active layers of the fifth transistors of the two first pixel circuits in the pixel circuit group are of an integral structure, and the second electrodes of the storage capacitors of the two first pixel circuits are of an integral structure.

16. The display substrate according to claim 15, further comprising: a second connection electrode; active layers of fifth transistors of two first pixel circuits in the pixel circuit group and second electrodes of storage capacitors of the two first pixel circuits are all electrically connected with the second connection electrode; and the second connection electrode is electrically connected with the first power supply line.

17. The display substrate according to claim 1, wherein the first display region comprises a plurality of display island regions spaced apart from each other, and light transmission regions located between adjacent display island regions; at least one of the plurality of display island regions comprises: the at least one pixel circuit group and at least one first light emitting element; the first pixel circuits in the pixel circuit group are electrically connected with the at least one first light emitting element, and the first pixel circuits are configured to drive the at least one first light emitting element to emit light; and first pixel circuits in adjacent display island regions are electrically connected to each other through a transparent connection line.

18. The display substrate according to claim 17, further comprising: a second display region located on at least one side of the first display region, and the second display region comprises a plurality of second pixel circuits arranged on the base substrate and a plurality of second light emitting elements, wherein at least one of the plurality of second pixel circuits is electrically connected to at least one of the plurality of second light emitting elements, and the at least one second pixel circuit is configured to drive the at least one second light emitting element to emit light; and a light transmittance of the first display region is greater than a light transmittance of the second display region.

19. A display apparatus, comprising: the display substrate according to claim 1, and a sensor located on a non-display side of the display substrate, wherein an orthographic projection of the sensor on the display substrate is overlapped with the first display region of the display substrate.

20. The display substrate according to claim 2, further comprising: a first initial signal line and a first reset control line; each first pixel circuit at least comprises a drive transistor and a first transistor, wherein a first electrode of the first transistor is electrically connected with the first initial signal line, a second electrode of the first transistor is electrically connected with a second electrode of the drive transistor, and a gate of the first transistor is electrically connected with the first reset control line; and
an active layer of the first transistor of the first pixel circuit extends along the first direction, and the gate of the first transistor extends along the second direction.
